(19) United States
(12) Patent Application Publication
(10) Pub. No.: US 2025/0237724 A1
(43) Pub. Date: Jul. 24, 2025

(54) MAGNETIC RESONANCE IMAGING APPARATUS AND STATIC MAGNETIC FIELD CORRECTION METHOD

(71) Applicant: CANON MEDICAL SYSTEMS CORPORATION, Otawara-shi (JP)

(72) Inventors: Hidekazu TANAKA, Nasushiobara (JP); Hiroki HATTORI, Nasushiobara (JP); Seiya TANAKA, Utsunomiya (JP)

(73) Assignee: CANON MEDICAL SYSTEMS CORPORATION, Otawara-shi (JP)

(21) Appl. No.: 19/017,887

(22) Filed: Jan. 13, 2025

(30) Foreign Application Priority Data
Jan. 24, 2024 (JP) 2024-008652

(51) Int. Cl. G01R 33/3873; G01R 33/38; G01R 33/385; G01R 33/561

(52) U.S. Cl. CPC G01R 33/3873; G01R 33/3804; G01R 33/385; G01R 33/5616

(57) ABSTRACT

A magnetic resonance imaging apparatus according to an exemplary embodiment includes a magnet, a gradient magnetic field coil, a sequence controller, and a plurality of metal shims. The magnet generates a static magnetic field. The gradient magnetic field coil applies a gradient magnetic field to a subject. The sequence controller applies a current to the gradient magnetic field coil by executing a first pulse sequence. The plurality of metal shims is used for passive shimming in which the plurality of metal shims is arranged based on the static magnetic field distribution in a state where a temperature of the gradient magnetic field coil is increased by execution of the first pulse sequence. The sequence controller executes a second pulse sequence for imaging the subject after completion of the passive shimming.

### CROSS-REFERENCE TO RELATED APPLICATIONS

This application is based upon and claims the benefit of priority from Japanese Patent Application No. 2024-008652, filed Jan. 24, 2024, the entire contents of which are incorporated herein by reference.

### FIELD

Embodiments described herein relate generally to magnetic resonance imaging apparatuses and static magnetic field correction methods.

### BACKGROUND

A magnetic resonance imaging (MRI) apparatus is an imaging apparatus that excites atomic nucleus spins of a subject placed in a static magnetic field with radio frequency (RF) signals having a Larmor frequency and reconstructs magnetic resonance signals (MR signals) generated from the subject with the excitation to generate an MR image.

To obtain an image having excellent image quality by the MRI apparatus, spatial homogeneity of the static magnetic field is demanded. Thus, for example, during installation of the MRI apparatus, metal shims are disposed at predetermined positions inside a gradient magnetic field coil to correct homogeneity of the static magnetic field. Homogenization of the static magnetic field using the metal shims is referred to as passive shimming.

During operation of the MRI apparatus, a temperature of each of the metal shims increases with a temperature rise of the gradient magnetic field coil, and magnetic susceptibility of each of the metal shims changes. The static magnetic field also changes with change of the magnetic susceptibility, and homogeneity of the static magnetic field adjusted during installation of the MRI apparatus degrades.

### BRIEF DESCRIPTION OF THE DRAWINGS

FIG. 1 is a schematic diagram illustrating an entire configuration example of a magnetic resonance imaging (MRI) apparatus according to a first exemplary embodiment;

FIG. 2 is a perspective view illustrating a schematic configuration of a gradient magnetic field coil disposed in the MRI apparatus according to the first exemplary embodiment;

FIG. 3 is a perspective view illustrating a detailed configuration example of each of a plurality of shim trays disposed in the MRI apparatus according to the first exemplary embodiment;

FIG. 4 is a flowchart illustrating a procedure of a static magnetic field correction method in the MRI apparatus according to the first exemplary embodiment;

FIG. 5 is a diagram illustrating an example of temperature raising means in the MRI apparatus according to the first exemplary embodiment;

FIG. 6 is a flowchart illustrating a procedure of a static magnetic field correction method in an MRI apparatus according to a first modification of the first exemplary embodiment;

FIG. 7 is a flowchart illustrating a procedure of a static magnetic field correction method in an MRI apparatus according to a second modification of the first exemplary embodiment;

FIG. 8 is a flowchart illustrating a procedure of a static magnetic field correction method in an MRI apparatus according to a second exemplary embodiment; and

FIG. 9 is a diagram illustrating an example of temperature raising means in the MRI apparatus according to the second exemplary embodiment.

### DETAILED DESCRIPTION

A magnetic resonance imaging apparatus according to an exemplary embodiment includes a magnet, a gradient magnetic field coil, a sequence controller, and a plurality of metal shims. The magnet generates a static magnetic field. The gradient magnetic field coil applies a gradient magnetic field to a subject. The sequence controller applies a current to the gradient magnetic field coil by executing a first pulse sequence. The plurality of metal shims is used for passive shimming in which the plurality of metal shim is arranged based on the static magnetic field distribution in a state where a temperature of the gradient magnetic field coil is increased by execution of the first pulse sequence. The sequence controller executes a plurality of second pulse sequences for imaging the subject after completion of the passive shimming.

In the following, exemplary embodiments of a magnetic resonance imaging apparatus and a static magnetic field correction method are described in detail with reference to drawings. A magnetic resonance imaging (MRI) apparatus 1 according to the exemplary embodiments can use a magnetic resonance imaging technique.

### First Exemplary Embodiment

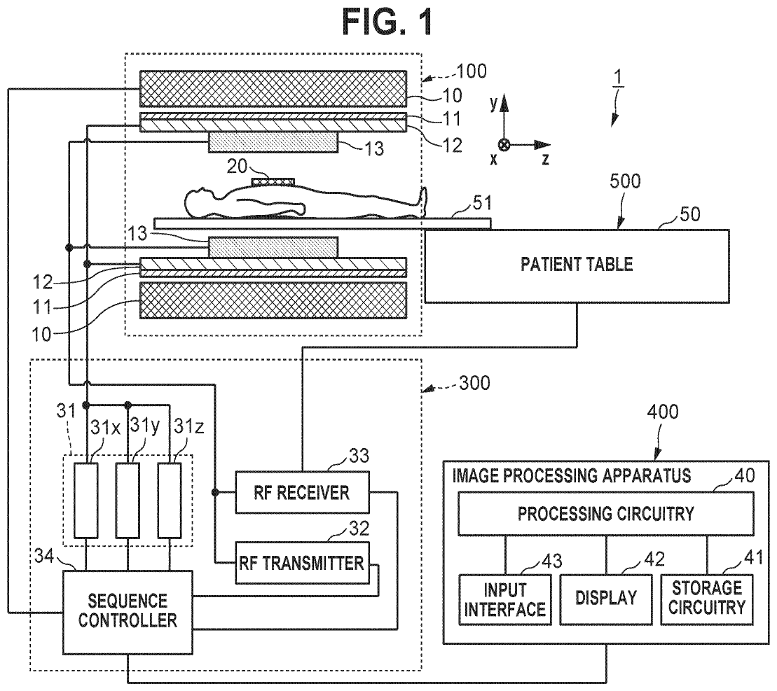

FIG. 1 is a schematic diagram illustrating an entire configuration example of the MRI apparatus 1 according to a first exemplary embodiment. As illustrated in FIG. 1, the MRI apparatus 1 includes a magnet rack 100, a control cabinet 300, an image processing apparatus 400 such as a console, and a patient table 500.

The magnet rack 100 and the patient table 500 are disposed in, for example, a shield room referred to as an examination room. The control cabinet 300 is disposed in, for example, a machine room, and the image processing apparatus 400 is disposed in, for example, an operation room. The image processing apparatus 400 may be connected to the MRI apparatus 1 through a network, and is installed in a remote place distant from the operation room.

The magnet rack 100 includes a static magnetic field magnet 10 as the magnet, a shim coil 11, a gradient magnetic field coil 12, and a whole body (WB) coil 13. These members are housed in a cylindrical housing.

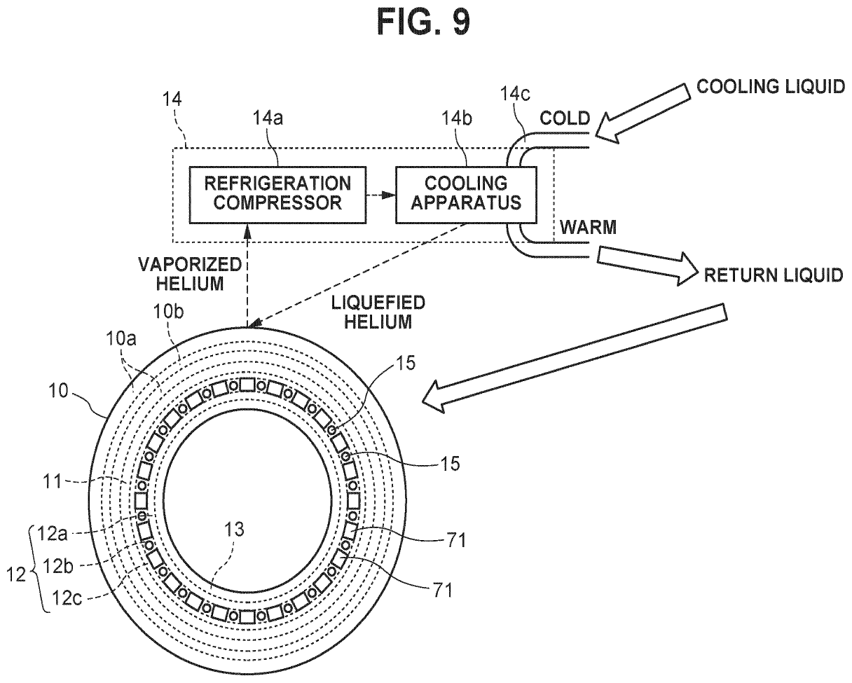

The static magnetic field magnet 10 of the magnet rack 100 is roughly classified into a tunnel type, where a magnet has a cylindrical magnet structure, and an open type, where paired magnets are disposed on an upper part and a lower part with an imaging space in between. In this example, a case where the static magnetic field magnet 10 is of the tunnel type is described; however, the type is not limited thereto. The static magnetic field magnet 10 has a substantially cylindrical shape, and generates a static magnetic field in a bore to which a subject P such as a patient is conveyed. The bore is a space inside the cylinder of the magnet rack 100. The static magnetic field magnet 10 includes a housing 10a (see FIG. 9) for holding liquid helium, a refrigerator 14 (see FIG. 9) for cooling the liquid helium to an extremely low temperature, and a superconducting coil 10b (see FIG. 9) inside the housing. The static magnetic field magnet 10 may be a resistive magnet or a permanent magnet. In the following, a case where the static magnetic field magnet 10 includes a superconducting coil is described.

The static magnetic field magnet 10 incorporates the superconducting coil, and the superconducting coil is cooled to the extremely low temperature by the liquid helium. A current supplied from a static magnetic field power supply is applied to the superconducting coil in an excitation mode, so that the static magnetic field magnet 10 generates a static magnetic field. Thereafter, when a mode is shifted to a permanent current mode, the static magnetic field power supply is disconnected. When the mode is shifted to the permanent current mode once, the static magnetic field magnet 10 continuously generates a large static magnetic field for a long time, for example, for one year or more.

The shim coil 11 has a substantially cylindrical shape as with the static magnetic field magnet 10, and is installed on an inner side of the static magnetic field magnet 10. The shim coil 11 is used for active shimming, and corrects first-order, second-order, and higher-order nonuniform components of the static magnetic field. The shim coil 11 includes a plurality of shim coils for correcting different nonuniform components of the static magnetic field.

The gradient magnetic field coil 12 has a substantially cylindrical shape as with the static magnetic field magnet 10, and for example, is installed on an inner side of the shim coil 11. The gradient magnetic field coil 12 applies a gradient magnetic field to the subject P by power supplied from a gradient magnetic field power supply 31. For example, the gradient magnetic field coil 12 may be configured to correct the first-order nonuniform component of the static magnetic field.

An eddy current occurring with generation of the gradient magnetic field inhibits imaging. Therefore, as the gradient magnetic field coil 12, an actively shielded gradient coil (ASGC) for reducing the eddy current is used. The ASGC is a gradient magnetic field coil including, for example, a main coil for generating gradient magnetic fields in an X-axis direction, a Y-axis direction, and a Z-axis direction, shim trays that can house a plurality of metal shims, and a shield coil for controlling a leakage magnetic field.

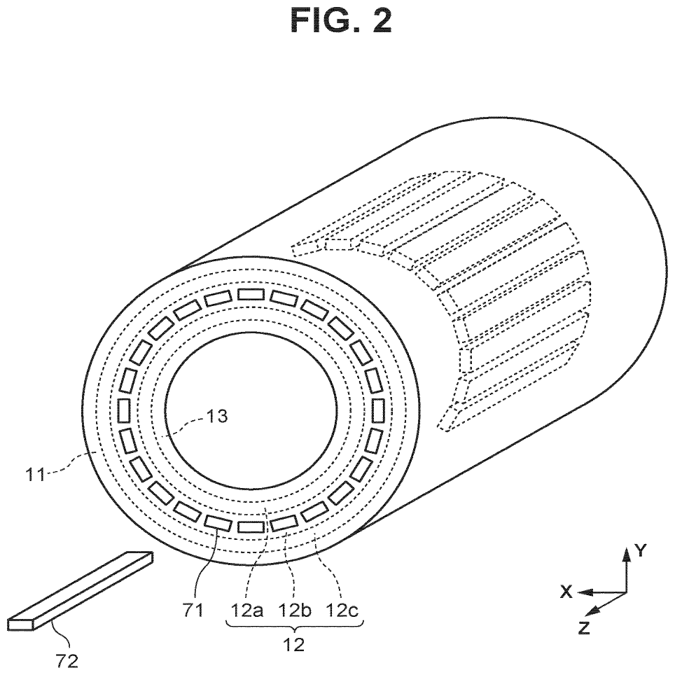

FIG. 2 is a perspective view illustrating a schematic configuration of the gradient magnetic field coil 12 disposed in the MRI apparatus 1 according to the first exemplary embodiment. As illustrated in FIG. 2, a shim tray unit 12b of the gradient magnetic field coil 12 has a substantially cylindrical shape, and is sandwiched between a main coil 12a and a shield coil 12c each having a substantially cylindrical shape. A plurality of slots 71 is disposed at substantially equal intervals in a circumferential direction of the shim tray unit 12b. The number and shapes of slots 71 disposed in the shim tray unit 12b are not particularly limited to the number and shapes illustrated in FIG. 2.

Each of the slots 71 is a through hole that has openings on both end surfaces of the shim tray unit 12b and extends over an entire length in a longitudinal direction (long axis direction) of the shim tray unit 12b. Shim trays 72 are insertable into the respective slots 71. The shim trays 72 are fixed to a substantially center part of the shim tray unit 12b. The substantially center part of the shim tray unit 12b in the Z-axis direction is also a center part of the gradient magnetic field coil 12 in the Z-axis direction. The shim trays 72 are made of, for example, a resin that is a non-magnetic and non-conductive material, and each have a substantially rod shape.

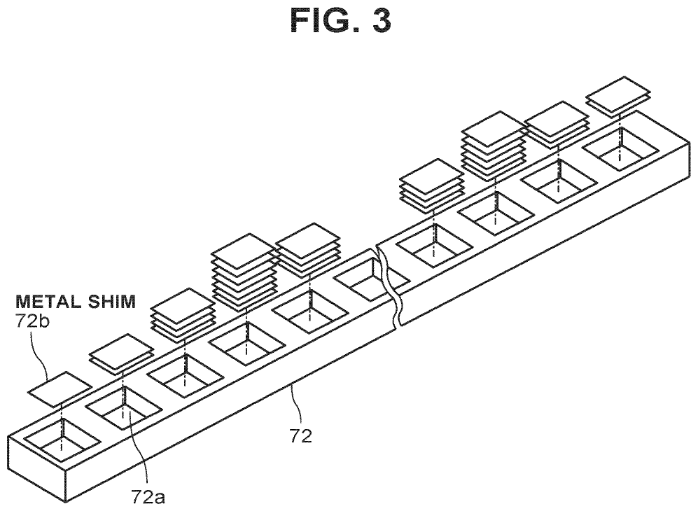

FIG. 3 is a perspective view illustrating a detailed configuration example of each of the plurality of shim trays 72 disposed in the MRI apparatus 1 according to the first exemplary embodiment. As illustrated in FIG. 3, a plurality of pockets 72a is disposed at predetermined intervals in a longitudinal direction in each of the shim trays 72. The number of pockets 72a is not particularly limited to the number illustrated in FIG. 3.

To homogenize the static magnetic field in an imaging region inside the bore, the necessary number of metal shims 72b are housed in the pockets 72a. A material of the respective metal shims 72b is, for example, a silicon steel sheet or permendur (alloy of iron and cobalt). Processing for adjusting the number of metal shims 72b housed in each of the pockets 72a to homogenize the static magnetic field in the imaging region inside the bore during installation of the MRI apparatus 1 is referred to as passive shimming.

The static magnetic field magnet 10 is designed and manufactured so as to homogenize the static magnetic field inside the bore as much as possible; however, a degree of inhomogeneity of the static magnetic field varies between individual apparatuses, and also depends on an ambient environment of an installation location of the apparatus. Therefore, during installation of the MRI apparatus 1, the passive shimming using the metal shims 72b is performed in general.

Referring back to FIG. 1, the WB coil 13 is also referred to as a whole-body radio frequency (RF) coil, and is installed in a substantially cylindrical shape on an inner side of the gradient magnetic field coil 12 so as to surround the subject P. The WB coil 13 transmits an RF pulse transmitted from an RF transmitter 32, to the subject P. The WB coil 13 receives magnetic resonance (MR) signals emitted from the subject P, for example, by excitation of hydrogen nuclei.

As illustrated in FIG. 1, the MRI apparatus 1 may include a local coil 20 in addition to the WB coil 13. The local coil 20 is also referred to as a local RF coil. The local coil 20 is placed in proximity to a body surface of the subject P. The local coil 20 may include a plurality of coil elements. The plurality of coil elements is arranged in an array inside the local coil 20, and is referred to as a phased array coil (PAC) in some cases.

The local coil 20 has several types. The local coil 20 has types of, for example, a head coil, a chest coil as illustrated in FIG. 1, an abdomen coil, a spine coil, and a knee coil. The local coil 20 has types of a reception-dedicated coil, a transmission-dedicated coil, and a transmission and reception coil for performing both transmission and reception. The local coil 20 is configured to be attachable to and detachable from a top board 51 through, for example, a cable.

The patient table 500 includes a patient table main body 50 and the top board 51. The patient table main body 50 can move the top board 51 in a vertical direction and a horizontal direction, and moves the subject P on the top board 51 to a predetermined height before imaging. Thereafter, the patient table main body 50 moves the top board 51 in the horizontal direction to move the subject P into the bore.

The control cabinet 300 includes the gradient magnetic field power supply 31 (X-axis power supply 31x, Y-axis power supply 31y, and Z-axis power supply 31z), the RF transmitter 32, an RF receiver 33, and a sequence controller 34.

The gradient magnetic field power supply 31 includes gradient magnetic field power supplies 31 for respective channels (X-axis power supply 31x, Y-axis power supply 31y, and Z-axis power supply 31z) for driving coils generating the gradient magnetic fields in the X-axis, the Y-axis, and the Z-axis. The gradient magnetic field power supplies 31 (X-axis power supply 31x, Y-axis power supply 31y, and Z-axis power supply 31z) independently outputs a necessary current waveform for each channel in response to an instruction from the sequence controller 34. As a result, the main coil 12a of the gradient magnetic field coil 12 can apply the gradient magnetic field in each of the X-axis direction, the Y-axis direction, and the Z-axis direction to the subject P.

The RF transmitter 32 generates an RF pulse in response to an instruction from the sequence controller 34. The RF pulse is transmitted to the WB coil 13 and is applied to the subject P. By application of the RF pulse, MR signals are generated from the subject P. The MR signals are received by the local coil 20 or the WB coil 13.

The MR signals received by the local coil 20, more specifically, the MR signals received by the coil elements of the local coil 20 are transmitted to the RF receiver 33. For a configuration in which the local coil 20 can transmit the MR signals to the RF receiver 33 through a cable, the MR signals received by the coil elements are transmitted to the RF receiver 33 through a cable disposed inside the patient table main body 50. Output paths from the coil elements and an output path from the WB coil 13 are referred to as channels. Thus, MR signals output from the coil elements and the WB coil 13 are referred to as channel signals in some cases. A channel signal received by the WB coil 13 is also transmitted to the RF receiver 33. MR signals received by the coil elements of the local coil 20 may be wirelessly transmitted to the RF receiver 33.

The RF receiver 33 performs analog-to-digital (A/D) conversion on channel signals, specifically, the MR signals, from the local coil 20 and the WB coil 13, and outputs the converted signals to the sequence controller 34. The MR signals converted into digital signals are also referred to as raw data in some cases.

The sequence controller 34 drives the gradient magnetic field power supply 31, the RF transmitter 32, and the RF receiver 33 to image the subject P under the control of the image processing apparatus 400 described below. The sequence controller 34 receives the raw data from the RF receiver 33 by imaging, and transmits the raw data to the image processing apparatus 400.

The sequence controller 34 includes processing circuitry (not illustrated). The processing circuitry includes hardware such as a processor executing a predetermined program, a field programmable gate array (FPGA), and an application specific integrated circuit (ASIC).

The image processing apparatus 400 includes processing circuitry 40, storage circuitry 41, a display 42, and an input interface 43.

The processing circuitry 40 includes a central processing unit (CPU) and a dedicated or general-purpose processor. The processor realizes various functions through software processing by executing various programs stored in the storage circuitry 41 or directly incorporated in the processing circuitry 40. The processing circuitry 40 controls operation of the sequence controller 34 to realize a function of performing imaging based on a pulse sequence to generate an MR image, a function of active shimming, and other functions. The processing circuitry 40 may include hardware such as an FPGA and an ASIC. Various functions described below can be realized by the hardware. The processing circuitry 40 may realize the various functions by combining software processing and hardware processing.

The storage circuitry 41 includes a storage medium, for example, a semiconductor memory element such as a random access memory (RAM) and a flash memory, and an external storage device such as hard disk and an optical disk. The storage circuitry 41 may be a portable medium such as a universal serial bus (USB) memory and a digital versatile disc (DVD).

The storage circuitry 41 stores various types of information and data, and various programs to be executed by the processor included in the processing circuitry 40.

The display 42 includes a common display output device such as a liquid crystal display and an organic light-emitting diode (OLED) display. The display 42 displays various types of information under the control of the processing circuitry 40. The display 42 may serve as a display device and a graphical user interface (GUI) for receiving various operations from a user, such as a touch panel.

The input interface 43 includes an input device operable by the user, and input circuitry for inputting a signal from the input device. The input device is realized by a track ball, a switch, a mouse, a keyboard, a touch pad, a touch screen, a non-contact input device using an optical sensor, an audio input device, and/or the like. When the user operates the input device, the input circuitry generates a signal corresponding to the operation, and outputs the signal to the processing circuitry 40.

As described above, during installation of the MRI apparatus 1, passive shimming using the metal shims 72b is performed in general. In the passive shimming, arrangement of the metal shims 72b is determined such that inhomogeneity of the static magnetic field falls within a predetermined allowable range during installation of the MRI apparatus 1. However, during operation of the MRI apparatus 1 (i.e., in imaging of subject P), the temperature of each of the metal shims 72b increases with a temperature rise of the gradient magnetic field coil 12, and the magnetic susceptibility of each of the metal shims 72b changes. The static magnetic field changes with the change of the magnetic susceptibility, which changes a center frequency and/or degrades the homogeneity of each of first-order, second-order, and higher-order static magnetic fields as compared with those during installation of the MRI apparatus 1. Change of the center frequency and degradation of homogeneity of the static magnetic field may degrade image quality.

To control the change of the center frequency and degradation of homogeneity of the static magnetic field, thermal insulation may be performed so as to prevent heat generated from the gradient magnetic field coil from being conducted to the metal shims, but degradation of homogeneity of the magnetic field may not be sufficiently controlled with increase in output of the gradient magnetic field coil. Further, the center frequency may be followed and corrected in real time, but homogeneity of first-order, second-order, and higher-order static magnetic fields cannot be sufficiently corrected only by correction of the center frequency in some cases.

Thus, in the static magnetic field correction method in the MRI apparatus 1 according to the exemplary embodiment, the passive shimming is performed in a state where a temperature environment of each of the gradient magnetic field coil 12 and the metal shims 72b during installation of the MRI apparatus 1 is brought close to a temperature environment during operation of the MRI apparatus 1.

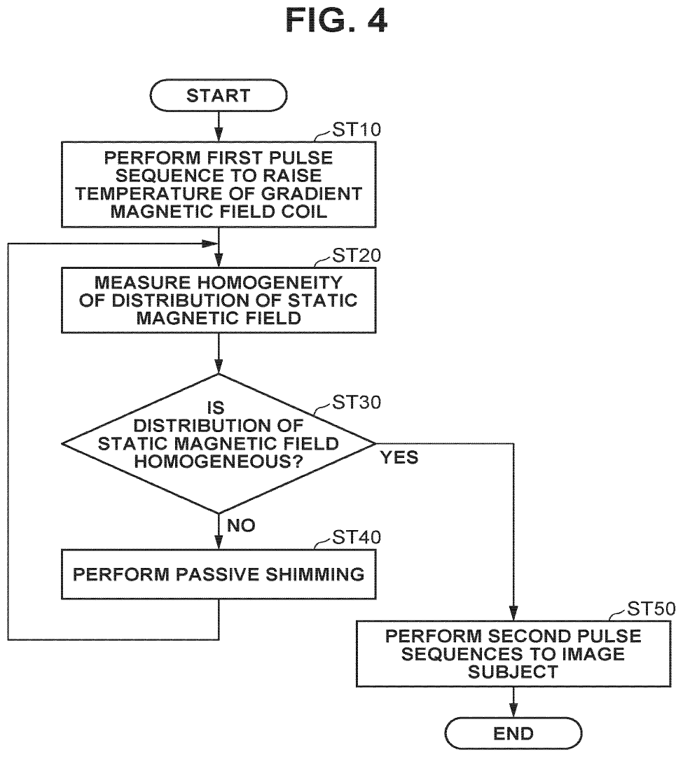

The static magnetic field correction method in the MRI apparatus 1 according to the first exemplary embodiment is described in detail. FIG. 4 is a flowchart illustrating a procedure of the static magnetic field correction method in the MRI apparatus 1 according to the first exemplary embodiment.

In step ST10, the sequence controller 34 applies a gradient magnetic field current for raising the temperature of the gradient magnetic field coil 12 to the gradient magnetic field coil 12 by executing a first pulse sequence. The first pulse sequence is a predetermined pulse sequence that can apply the gradient magnetic field current for raising the temperature of the gradient magnetic field coil 12 to the gradient magnetic field coil 12. A type of the first pulse sequence and an imaging condition are not limited, and a known type of the pulse sequence and a known imaging condition can be used. The first pulse sequence is performed before the passive shimming.

The first pulse sequence is performed, so that the temperature environment of the gradient magnetic field coil 12 and the metal shims 72b is brought close to the temperature environment during operation of the MRI apparatus 1.

The sequence controller 34 performs, among a plurality of second pulse sequences, a pulse sequence with which the temperature of the gradient magnetic field coil 12 becomes the highest, as the first pulse sequence. The second pulse sequences are predetermined pulse sequences for imaging the subject P. Types of the second pulse sequences and an imaging condition are not limited, and a known type of the pulse sequence and a known imaging condition that can be set by, for example, user input through the input interface 43 or reading of a condition stored in the storage circuitry 41 can be used.

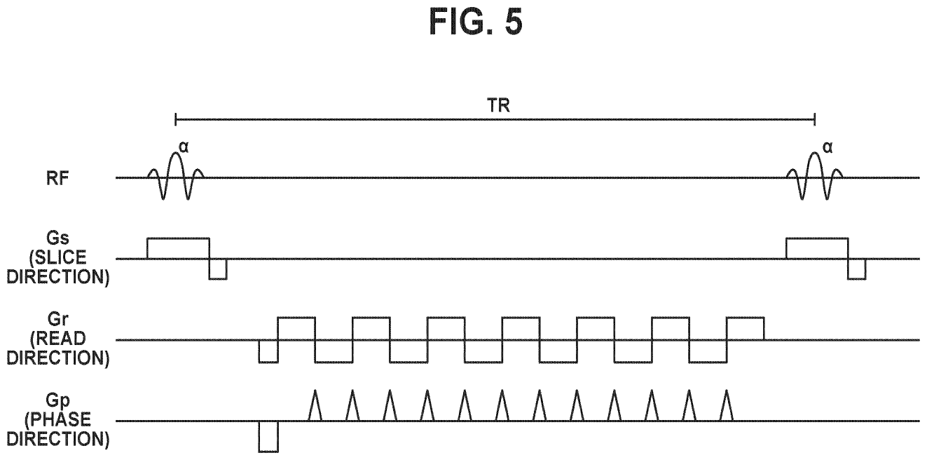

The sequence controller 34 may perform echo planer imaging (EPI) as the first pulse sequence. FIG. 5 is a sequence diagram of a gradient echo (GRE)-EPI which is an example of the pulse sequence for raising the temperature. As illustrated in FIG. 5, the EPI is a pulse sequence with a large thermal load because the EPI inverts a gradient of the gradient magnetic field at high speed. The large thermal load results in local heat generation distribution in the gradient magnetic field coil 12. Thus, the passive shimming is performed in a state where the gradient magnetic field coil 12 has a local heat generation distribution. The pulse sequence of the EPI to be performed as the first pulse sequence is not limited to the GRE-EPI illustrated in FIG. 5, and may be spin echo (SE)-EPI, diffusion EPI, single-shot EPI, or multi-shot EPI.

In step ST20, homogeneity of the static magnetic field distribution which is magnetic field characteristics of the static magnetic field magnet 10 is measured. For example, in a state where the plurality of pockets 72a are all empty, specifically, in a state where no metal shims 72b are arranged, the magnetic field is measured at many points at the center part of the bore. At the time point of first-time step ST20, the measured homogeneity of the static magnetic field is not secured because it is before the passive shimming. The measurement is performed using an optional magnetic field measuring device. In the measurement of the magnetic field, not all the pockets 72a are necessarily empty, and some metal shims 72b may be previously disposed. The processing in step ST20 is performed by, for example, the processing circuitry 40.

In step ST30, it is determined whether the static magnetic field distribution is homogeneous. For example, it is determined whether inhomogeneity of the static magnetic field falls within the predetermined allowable range. If it is determined that the static magnetic field distribution is homogeneous (YES in step ST30), it is determined that the passive shimming, in other words, installation of the MRI apparatus 1 is completed, and the processing proceeds to step ST50. If it is determined that the static magnetic field distribution is not homogeneous (NO in step ST30), the passive shimming is to be performed again, and the processing proceeds to step ST40. The operation in step ST30 is performed by, for example, the processing circuitry 40.

In step ST40, the passive shimming is performed based on a measurement result of homogeneity of the static magnetic field distribution. The plurality of metal shims for the passive shimming is arranged such that the static magnetic field distribution is homogenized in a state where the temperature of the gradient magnetic field coil 12 is increased by execution of the first pulse sequence. After the plurality of metal shims is arranged, the operation in step ST20 is performed. The operations in steps ST20 to ST40 are repeated until inhomogeneity of the static magnetic field falls within the predetermined allowable range. In other words, the operations up to step ST40 correspond to installation of the MRI apparatus 1, and the operations after step ST40 correspond to operations during the operation of the MRI apparatus 1.

In step ST50, the sequence controller 34 performs a plurality of second pulse sequences for imaging the subject P. The operation in step ST50 is performed after completion of the passive shimming.

As described above, when the first pulse sequence performed before the passive shimming is the pulse sequence with which the temperature of the gradient magnetic field coil 12 becomes the highest, the EPI, or the like, high homogeneity of the static magnetic field is secured in the state where the thermal load is large during installation of the MRI apparatus 1. Thus, even in a case where the plurality of second pulse sequences for imaging the subject P is a pulse sequence with a large thermal load such as the EPI, degradation of imaging quality can be controlled.

There is a case where the thermal load during installation of the MRI apparatus 1 and the thermal load during operation of the MRI apparatus 1 are different from each other. This is, for example, a case where after the passive shimming is performed with the pulse sequence with which the temperature of the gradient magnetic field coil 12 becomes the highest, the EPI, or the like serving as the first pulse sequence, the subject P is imaged with a pulse sequence causing a small thermal load serving as each of the second pulse sequences. In such a case, homogeneity of the static magnetic field distribution may be insufficiently secured during operation of the MRI apparatus 1.

Thus, the sequence controller 34 may perform, as the first pulse sequence, a pulse sequence that brings the gradient magnetic field coil 12 to a thermal load state with a thermal load between one in a no-load state where no thermal load is applied to the gradient magnetic field coil 12 and one in a maximum thermal load state to be induced by the pulse sequence with which the temperature of the gradient magnetic field coil 12 becomes the highest. For example, the pulse sequence that brings the gradient magnetic field coil 12 to the thermal load state with a thermal load substantially intermediate between one in the no-load state and one in the maximum thermal load state is set to the first pulse sequence and the passive shimming is performed, so that it is possible to substantially secure homogeneity of the static magnetic field distribution in the no-load state and homogeneity of the static magnetic field distribution in the maximum load state. Therefore, in both the case where the plurality of second pulse sequences for imaging the subject P is the pulse sequence with the large thermal load and the case where the plurality of second pulse sequences for imaging the subject P is the pulse sequence with the small thermal load, degradation of imaging quality can be controlled.

### (First Modification)

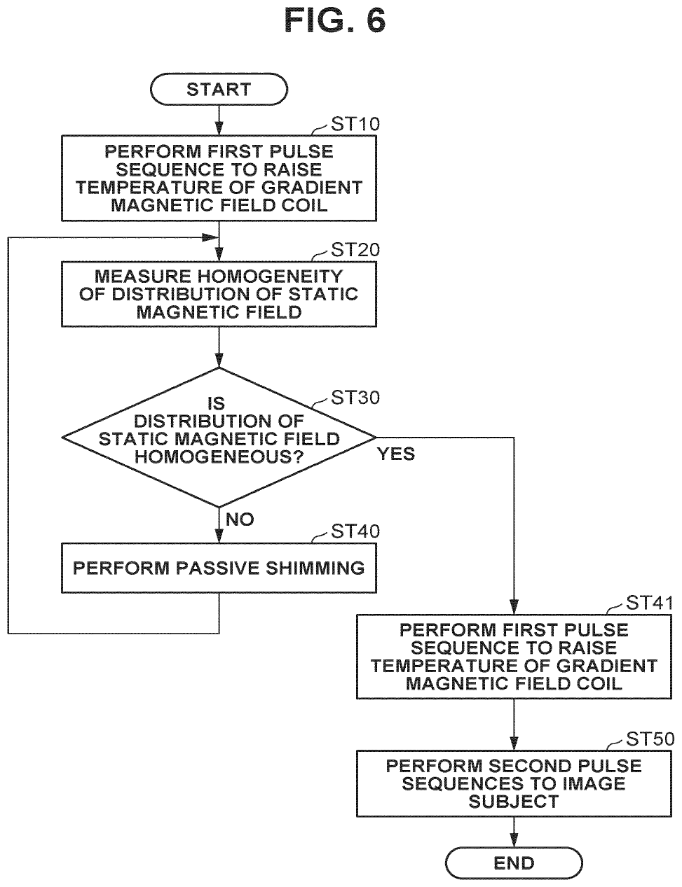

FIG. 6 is a flowchart illustrating a procedure of a static magnetic field correction method in an MRI apparatus 1 according to a first modification of the first exemplary embodiment. As illustrated in FIG. 6, in the first modification, if a determination result is YES in step ST30, the operation in step ST41 is performed before the operation in step ST50. In FIG. 6, the steps same as the steps illustrated in FIG. 4 are denoted by the same reference numerals, and descriptions of the steps are omitted.

In step ST41, after the passive shimming is completed and before the plurality of second pulse sequences for imaging the subject P is performed (i.e., before step ST50), the sequence controller 34 further performs the first pulse sequence to raise the temperature of the gradient magnetic field coil 12.

When the first pulse sequence is performed before the second pulse sequences are performed, the temperature environment at execution of the plurality of second pulse sequences for imaging the subject P is brought close to the temperature environment in the passive shimming with the temperature of the gradient magnetic field coil 12 increased. In other words, the plurality of second pulse sequences for imaging the subject P is performed in a state where high homogeneity of the static magnetic field is secured. Thus, in both the case where the plurality of second pulse sequences for imaging the subject P is the pulse sequence with the large thermal load and the case where the plurality of second pulse sequences for imaging the subject P is the pulse sequence with the small thermal load, degradation of imaging quality can be controlled.

### (Second Modification)

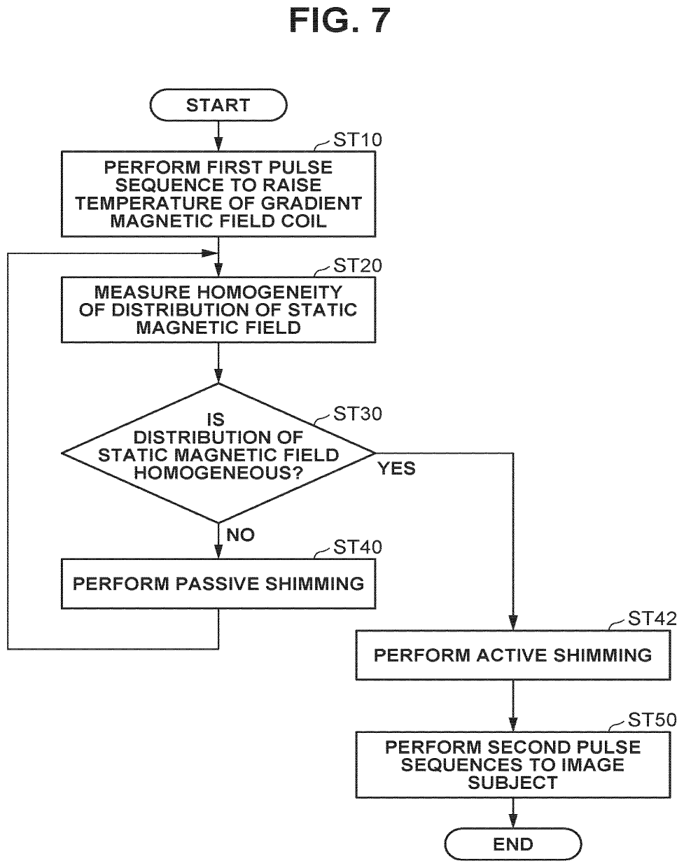

FIG. 7 is a flowchart illustrating a procedure of a static magnetic field correction method in an MRI apparatus 1 according to a second modification of the first exemplary embodiment. As illustrated in FIG. 7, in the second modification, if the determination result is YES in step ST30, the operation in step ST42 is performed before the operation in step ST50. In FIG. 7, the steps same as the steps illustrated in FIG. 4 are denoted by the same reference numerals, and descriptions of the steps are omitted.

In step ST42 before the plurality of second pulse sequences for imaging the subject P is performed, active shimming may be performed such that the static magnetic field distribution is homogenized based on the second pulse sequences and the imaging condition.

More specifically, the active shimming using the shim coil 11 is performed for inhomogeneity of the static magnetic field based on the second pulse sequences and/or imaging conditions, thus correcting the center frequency and the homogeneity of each of first-order, second-order, and higher-order static magnetic fields. When the active shimming is performed in addition to the passive shimming, even in a case where the thermal load during installation of the MRI apparatus 1 and the thermal load during operation of the MRI apparatus 1 are different from each other, inhomogeneity of the static magnetic field can fall within the allowable range.

Temporal and spatial change of inhomogeneity of the static magnetic field corresponding to the thermal load may be previously stored in a database and the storage circuitry 41, and the active shimming may be performed such that the static magnetic field distribution is homogenized. In the second modification, a difference in homogeneity of the static magnetic field caused by difference between the thermal load during installation of the MRI apparatus 1 and the thermal load during operation of the MRI apparatus 1 can be complemented. In this case, to wholly cover degradation of homogeneity of the static magnetic field caused by heat generation of the gradient magnetic field coil 12 only through the active shimming, the output of the shim coil 11 is to be increased and inductance of the shim coil 11 is to be reduced. Thus, a correction amount through the active shimming is desirably small as much as possible. The thermal load is applied and the passive shimming is performed during the installation of the MRI apparatus 1, thus reducing the correction amount through the active shimming.

### Second Exemplary Embodiment

In the MRI apparatus 1 according to the first exemplary embodiment, the thermal load during installation of the MRI apparatus 1 is applied by execution of the first pulse sequence. The MRI apparatus 1 according to a second exemplary embodiment is different from the MRI apparatus 1 according to the first exemplary embodiment in that the thermal load during installation of the MRI apparatus 1 is applied by circulating heated liquid through a pipe 15 arranged around the gradient magnetic field coil 12. Repetitive descriptions about the configurations substantially same as those in the MRI apparatus 1 according to the first exemplary embodiment illustrated in FIG. 1 are omitted.

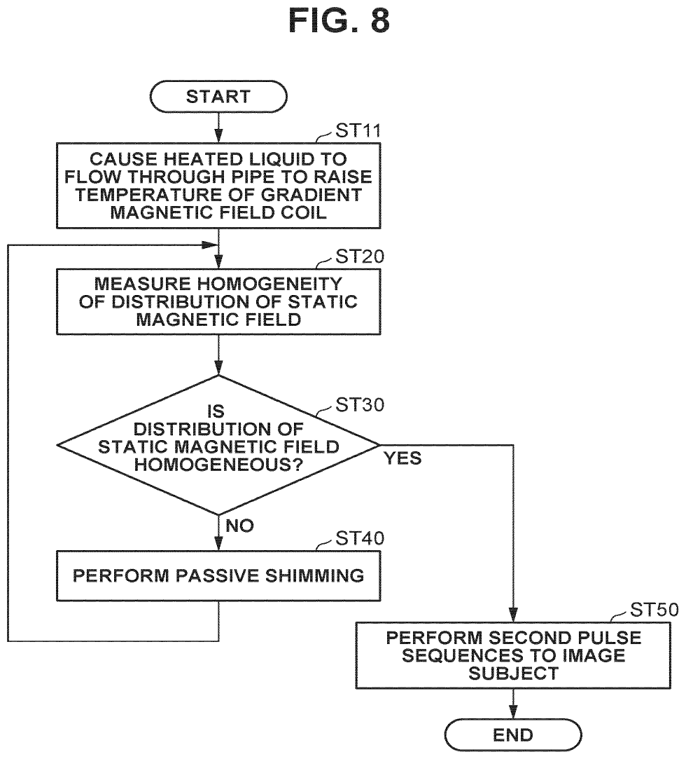

FIG. 8 is a flowchart illustrating a procedure of a static magnetic field correction method according to the MRI apparatus 1 according to the second exemplary embodiment. As illustrated in FIG. 8, in the second exemplary embodiment, to apply the thermal load during installation of the MRI apparatus 1, the operation in step ST11 is performed in place of the operation in step ST10 illustrated in FIG. 4. After step ST11, the processing proceeds to step ST20. In FIG. 8, the steps same as the steps illustrated in FIG. 4 are denoted by the same reference numerals, and descriptions of the steps are omitted.

In step ST11, the heated liquid is caused to flow through the pipe 15 to raise the temperature of the gradient magnetic field coil 12. The heated liquid for raising the temperature of the gradient magnetic field coil 12 is circulated through the pipe 15. A temperature of the circulated liquid is desirably a temperature close to, for example, the temperature environments of the gradient magnetic field coil 12 and the metal shims that are induced by heat generation due to the pulse sequence for imaging the subject P.

FIG. 9 is a diagram illustrating an example of the pipe 15 arranged around the gradient magnetic field coil 12 to be raised in temperature. The arrangement, the number, and a shape of the pipe 15 are not limited to those illustrated in FIG. 9, and may be, for example, arrangement, the number, and a shape of a known cooling liquid flow path disposed for cooling the gradient magnetic field coil. The position around the gradient magnetic field coil 12 may be a position between the main coil 12a and the shield coil 12c of the gradient magnetic field coil 12, a position between the gradient magnetic field coil 12 and the shim coil 11, or a position between the gradient magnetic field coil 12 and the WB coil 13.

The refrigerator 14 includes a refrigeration compressor 14a, a cooling apparatus 14b, and a cooling liquid pipe 14c. The refrigeration compressor 14a mechanically compresses vaporized helium, the cooling apparatus 14b liquefies the vaporized helium, and the liquefied helium is circulated in the static magnetic field magnet 10. The cooling apparatus 14b liquefies the compressed helium by using, for example, cooling liquid (e.g., cooling water) flowing through the cooling liquid pipe 14c. Return liquid of the cooling liquid is increased in temperature because of being used for cooling. Thus, the return liquid can be used as liquid for raising the temperature of the gradient magnetic field coil 12. The heated liquid to be caused to flow through the pipe 15 may be the return liquid of the refrigerator 14 used by the static magnetic field magnet 10.

In other words, in the second exemplary embodiment, the metal shims are arranged such that the static magnetic field distribution is homogenized in a state where the temperature of the gradient magnetic field coil 12 is increased by circulation of the heated liquid. The sequence controller 34 performs the pulse sequences for imaging the subject after completion of the passive shimming.

Alternatively, the temperature may be increased to a temperature close to the temperatures in the temperature environments of the gradient magnetic field coil 12 and the metal shims caused by heat generation of the pulse sequence for imaging the subject P, by using a heater or the like disposed near the metal shims. The first exemplary embodiment, the first modification of the first exemplary embodiment, and the second modification of the first exemplary embodiment can be implemented in combination with the second exemplary embodiment.

The MRI apparatus 1 and the static magnetic field correction method according to at least one exemplary embodiment described above can control degradation of homogeneity of the static magnetic field during operation of the MRI apparatus.

The term “processor” used in the description of the foregoing exemplary embodiments refers to a circuit such as a central processing unit (CPU), a graphics processing unit (GPU), an application specific integrated circuit (ASIC), and a programmable logic device (e.g., a simple programmable logic device [SPLD], a complex programmable logic device [CPLD], or a field programmable gate array [FPGA]). The processor realizes the various types of functions by reading out and executing programs stored in the storage medium.

The functions of the processing circuitry may be realized by a single processor, or a plurality of independent processors may be combined to configure processing circuitry, and each of the processors may realize a corresponding function. In a case where the plurality of processors is disposed, the storage medium storing programs may be individually disposed for each processor, or one storage medium may collectively store programs corresponding to the functions of all processors.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus, comprising:
a magnet configured to generate a static magnetic field;
a gradient magnetic field coil configured to apply a gradient magnetic field to a subject;
a sequence controller configured to apply a current to the gradient magnetic field coil by executing a first pulse sequence; and
a plurality of metal shims used for passive shimming in which the plurality of metal shims is arranged based on a distribution of the static magnetic field in a state where a temperature of the gradient magnetic field coil is increased by execution of the first pulse sequence,
wherein the sequence controller is configured to perform a pulse sequence for imaging the subject after completion of the passive shimming.

2. The magnetic resonance imaging apparatus according to claim 1, wherein the sequence controller is configured to execute, as the first pulse sequence, a pulse sequence with which the temperature of the gradient magnetic field coil becomes highest among a plurality of the second pulse sequences to be performed for imaging the subject.

3. The magnetic resonance imaging apparatus according to claim 1, wherein the sequence controller is configured to execute echo planer imaging (EPI) as the first pulse sequence.

4. The magnetic resonance imaging apparatus according to claim 1, wherein, after completion of the passive shimming and before execution of the second pulse sequence for imaging the subject, the sequence controller is configured to execute the first pulse sequence to raise the temperature of the gradient magnetic field coil.

5. The magnetic resonance imaging apparatus according to claim 1, wherein, before execution of the second pulse sequence for imaging the subject, active shimming is performed based on the second pulse sequence and an imaging condition such that the distribution of the static magnetic field is homogenized.

6. A magnetic resonance imaging apparatus, comprising:
a magnet configured to generate a static magnetic field;
a gradient magnetic field coil configured to apply a gradient magnetic field to a subject;
a pipe arranged around the gradient magnetic field coil and configured to circulate heated liquid for raising a temperature of the gradient magnetic field coil;
a plurality of metal shims used for passive shimming, and arranged based on a distribution of the static magnetic field in a state where a temperature of the gradient magnetic field coil is increased by circulation of the heated liquid; and
a sequence controller configured to perform a pulse sequence for imaging the subject after completion of the passive shimming.

7. The magnetic resonance imaging apparatus according to claim 6, further comprising a refrigerator used in the s magnet,
wherein the heated liquid to be circulated through the pipe is return liquid of the refrigerator used in the magnet.

8. A static magnetic field correction method for a magnetic resonance imaging apparatus, the magnetic resonance imaging apparatus including a magnet configured to generate a static magnetic field, a gradient magnetic field coil configured to apply a gradient magnetic field to a subject, metal shims used for passive shimming, and a sequence controller configured to execute a second pulse sequence for imaging the subject after completion of the passive shimming, the static magnetic field correction method comprising:
causing the sequence controller to apply a current to the gradient magnetic field coil by executing a first pulse sequence; and
arranging the plurality of metal shims based on a distribution of the static magnetic field in a state where a temperature of the gradient magnetic field coil is increased by execution of the first pulse sequence.
